(19) United States
(12) Patent Application Publication
(10) Pub. No.: US 2004/0182310 A1
(43) Pub. Date: Sep. 23, 2004

(54) CVD device with substrate holder with differential temperature control

(76) Inventor: Johannes Kaeppeler, Wurselen (DE)

Correspondence Address: ST. ONGE STEWARD JOHNSTON & REENS, LLC, 986 BEDFORD STREET, STAMFORD, CT, 06905-5619, US

(21) Appl. No.: 10/751,390

(22) Filed: Jan. 5, 2004

Related U.S. Application Data
(63) Continuation of application No. PCT/EP02/04405, filed on Apr. 22, 2002.

(30) Foreign Application Priority Data
Jul. 4, 2001 (DE) 101 32 448.0

(51) Int. Cl. C30B 1/00

(52) U.S. Cl. 117/200

(57) ABSTRACT

The invention relates to a device for depositing especially crystalline layers on an especially crystalline substrate, comprising a high-frequency heated substrate support from a conductive material on which the substrate is two-dimensionally supported, and which comprises a zone of higher conductivity. The system is specifically characterized in that the higher conductivity zone is associated with the surface of support of the substrate and substantially corresponds to the area occupied by the substrate. Further, the zone on which the substrate rests heats up more than the substrate surface surrounding the substrate.

This application is a continuation of pending International Patent Application No. PCT/EP02/04405 filed Apr. 22, 2002 which designates the United States and claims priority of pending German Application No. 101 32 448.0 filed Jul. 4, 2001.

### FIELD OF INVENTION

The invention relates to a device for depositing in particular crystalline layers on an in particular crystalline substrate, having a high-frequency-heated substrate holder made from conductive material for holding the substrate with surface-to-surface contact, which substrate holder has zones of higher electrical conductivity.

DE 199 40 033 describes a CVD device of this type. This document describes a device for depositing in particular silicon carbide layers in a reactor, the walls of which form a flow passage which is heated on all sides. In this case, thin plates of inert material, for example tantalum, molybdenum or tungsten, are to be fitted in the flow passage and in particular in the region of the substrate holder, in order to locally influence the high-frequency coupling and thereby the introduction of energy.

Considerable radiation losses occur at the surface of the substrate holder of devices which are used to deposit crystalline layers on in particular crystalline substrates and in which only the substrate holder is heated, whereas the remaining reactor walls are not actively heated. The level of the radiation losses is highly dependent on the quality of the surface of the substrate holder. The substrate holder is generally only partially occupied by substrates. On account of manufacturing-related inaccuracies and/or thermal distortion, gaps which have an insulating effect are formed between the substrate and the surface of the substrate holder. The invention also relates to devices in which the substrates rest on separate substrate bearing disks which are located in cutouts in the substrate holder. In these devices, the substrate bearing disks are located on a gas bearing which rotates, so that the substrate holder bearing disks are driven in rotation. This gas gap, which is present between substrate bearing disk and the base of the cutout, forms an insulating layer. This also has the consequence that the substrate temperature is lower than the surface temperature of the substrate holder in the immediate vicinity of the substrate.

This temperature difference has an adverse effect on the layer growth characteristics.

The invention is therefore based on the object of providing measures for making the temperature profile in the region of the substrate holder or in the layer of gas immediately above it more uniform.

The object is achieved firstly and substantially by the subject matter of Claim 1, in which the zone of higher conductivity is associated with the supported surface of the substrate. The subjects described in the further claims relate both to advantageous refinements of the subject matter of Claim 1 and also at the same time to stand-alone proposed technical solutions which are independent of the subject matter of Claim 1 and of the objective referred to above. It is proposed therein for the zone of higher conductivity to substantially correspond to the area taken up by the substrate. Furthermore, it is provided that the zone be formed by an insert piece made from metal. It is advantageous if each of a multiplicity of substrates resting on the substrate holder is located above a zone of higher electrical conductivity, which zone has the same surface dimensions as the substrate. This ensures that the substrate is located on a zone of the substrate holder which is hotter than the substrate holder surface surrounding the substrate. This configuration makes it possible to compensate for heat transfer losses. Furthermore, this configuration also has the associated advantage that by suitable over-dimensioning of the zones of higher electrical conductivity, it is possible to generate a temperature profile in which the zones of the substrate holder on which the substrates are located are hotter than the surface of the substrate holder surrounding the substrates. It is considered particularly advantageous for the substrate holder to have one or more substrate bearing disks, which in particular are mounted on rotary gas bearings and each have an associated insert piece. The insert piece or the zone of higher electrical conductivity may in this case be associated with the substrate bearing disk itself. It is particularly advantageous if the entire substrate bearing disk consists of metal. However, in order to minimize the dimensions of the substrate bearing disk, there is also provision for the substrate bearing disk to be located on a gas bearing in a bearing recess of the substrate holder and for the insert piece or the zone of higher electrical conductivity to be associated with the base of the bearing recess. Suitable materials for the insert piece are molybdenum, tantalum or tungsten. An inert material is preferred. The substrate holder may be surrounded by a high-frequency coil. This may be a tunnel reactor. Alternatively, however, the substrate holder may also be configured as a cylindrical disk which is disposed above a high-frequency coil formed as a planar coil. With this type of “planetary reactor”, the substrate holder disk itself can rotate. The individual substrate bearing disks, referred to as planets, in turn rotate about their own axes. To absorb the centrifugal forces which occur as a result of the substrate holder rotation and act on the substrate bearing disks, it is possible for the bearing recesses to provide central bearing pins which engage in associated bearing recesses in the substrate bearing disks.

### BRIEF DESCRIPTION OF DRAWINGS

Exemplary embodiments of the invention are explained below with reference to appended drawings, in which:

FIG. 1 shows, a plan view, a rotationally driven substrate holder which is in the form of a circular disk and has substrate bearing disks arranged in planetary fashion and rotating about their own axes as they rest on a gas bearing,

FIG. 2 shows a section on line II-II in FIG. 1,

FIG. 3 shows a partial illustration, corresponding to FIG. 2, of a variant,

FIG. 4 shows an illustration corresponding to FIG. 3 of a further variant,

FIG. 5 shows a cut-away, perspective illustration of a tunnel reactor, and

FIG. 6 shows a section on line VI-VI in FIG. 5.

### DETAILED DESCRIPTION OF DRAWINGS

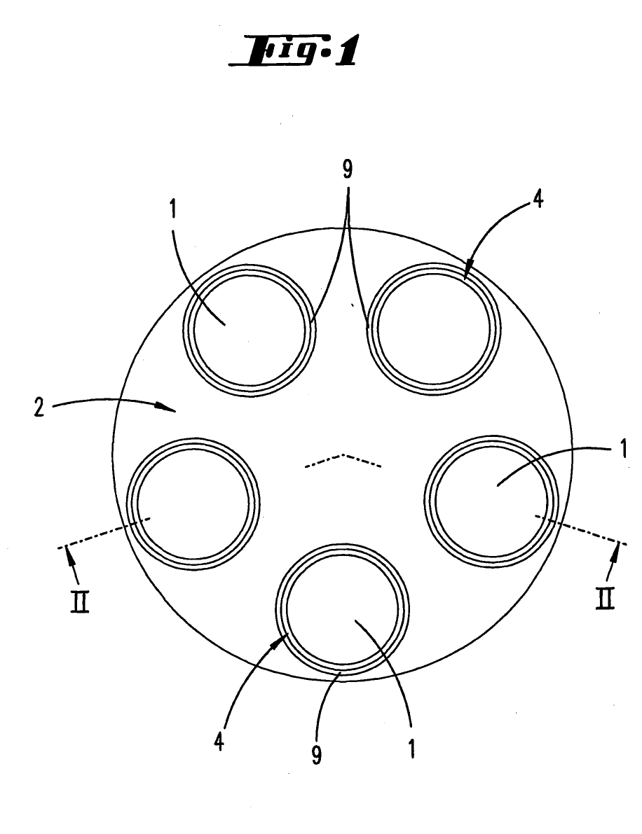

The substrate holder 2 illustrated in FIGS. 1-4 comprises a block of graphite which is in the form of a cylindrical disk and is located in a reactor, driven in rotation about its own axis. The reactive gases are introduced into the process chamber through a feed line disposed above and in the center of the substrate holder. The walls of this process chamber are not heated. They are only heated by the radiation of the substrate holder 2, which is heated from below by means of an HF coil 5. The result of this is that there is a temperature drop inside the process chamber from the substrate holder 2 toward the process chamber walls (not shown). The reactive gases which are introduced into the process chamber and which may be trimethyl-gallium, trimethyl-indium, arsine and/or phosphine, partially decompose in the gas phase and on the substrate surface. On the substrate surface, the decomposition products form a semiconductor layer comprising III-V material. Since the decomposition reaction, at least of the III starting materials, is to take place substantially only on the substrate surface and not on the adjacent substrate holder, it is necessary for the temperature of the substrate surface to be higher than the temperature of the surface of the substrate holder area which adjoins the substrate. Accordingly, the invention deals with a refinement of a known MOCVD reactor.

To bring the temperature of the substrate 1 at least to the temperature corresponding to the temperature of the surface of the substrate holder 2 surrounding the substrate, there is provision for insert pieces 3 made from metal to be placed inside the substrate holder 2 beneath the substrate 1. Suitable metals are tungsten, tantalum or preferably molybdenum. This metal inlay, which extends beneath the substrate 1 substantially covering the surface, causes the high frequency emitted by the HF coil 5 to be more strongly coupled. This leads to increased conversion of heat in the insert piece 3. As a result, the substrate 1, which is located almost directly above the insert piece 3, is heated to a greater extent than the substrate holder surrounding the substrate 1.

In the exemplary embodiment illustrated in FIG. 2, the substrate 1 rests on a substrate bearing disk 4 in such a manner as to virtually fill the surface area. The substrate bearing disk 4 likewise consists of graphite. However, on its underside, which is disposed opposite the base of the bearing recess 9, it has an insert piece 3 made from molybdenum. Apart from a narrow edge strip, the size of the insert piece 3 corresponds to the substrate bearing disk 4, which is in the form of a circular disk. To mount the substrate bearing disk 4 in a centered position, the insert piece 3 has a bearing opening 8 in its center. A bearing pin 7 which projects from the center of the base of the bearing recess 9 engages in the bearing opening 8 in order to hold the substrate bearing disk 4 rotating on a gas bearing in a centered position when the entire substrate holder 2 is rotating about its own axis. The substrate bearing disk 4 is driven in a rotation in a known way by means of a gas flow which flows through passages (not shown) in the substrate holder 2. These passages open out into helical grooves in the base of the bearing recess 9 and cause the substrate bearing disk 4 to rotate through viscous forces.

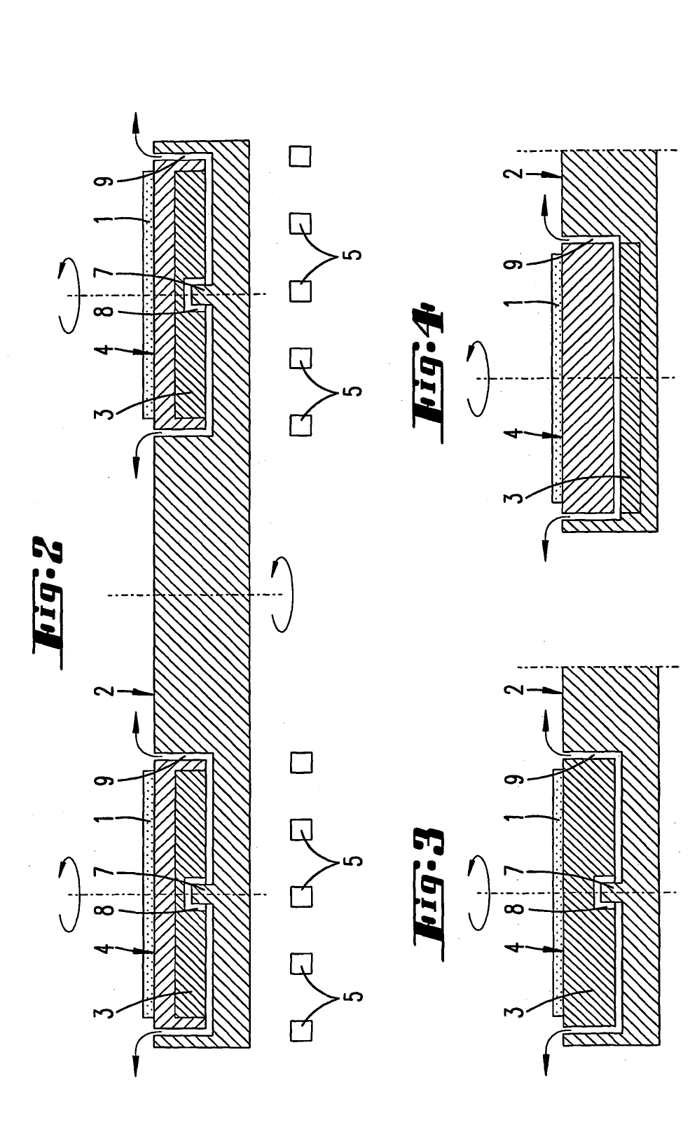

In the exemplary embodiment illustrated in FIG. 3, the entire substrate bearing disk 4 is configured as a metal block.

In the exemplary embodiment illustrated in FIG. 4, the substrate bearing disk 4 is made entirely from graphite. In this configuration, it is possible to dispense with the bearing pin 7, since the mass of the substrate bearing disk 4 is lower than that in the exemplary embodiment shown in FIG. 3. In the exemplary embodiment shown in FIG. 4, an insert piece 3 made from molybdenum is located beneath the substrate bearing disk 4 in the substrate holder 2, with an approximately identical surface area. The surface of the insert piece 3, which is uncovered at the top, forms the base of the bearing recess 9. The passages through which the gas flows in order to maintain the rotationally driving gas bearing, can run through the molybdenum block 3.

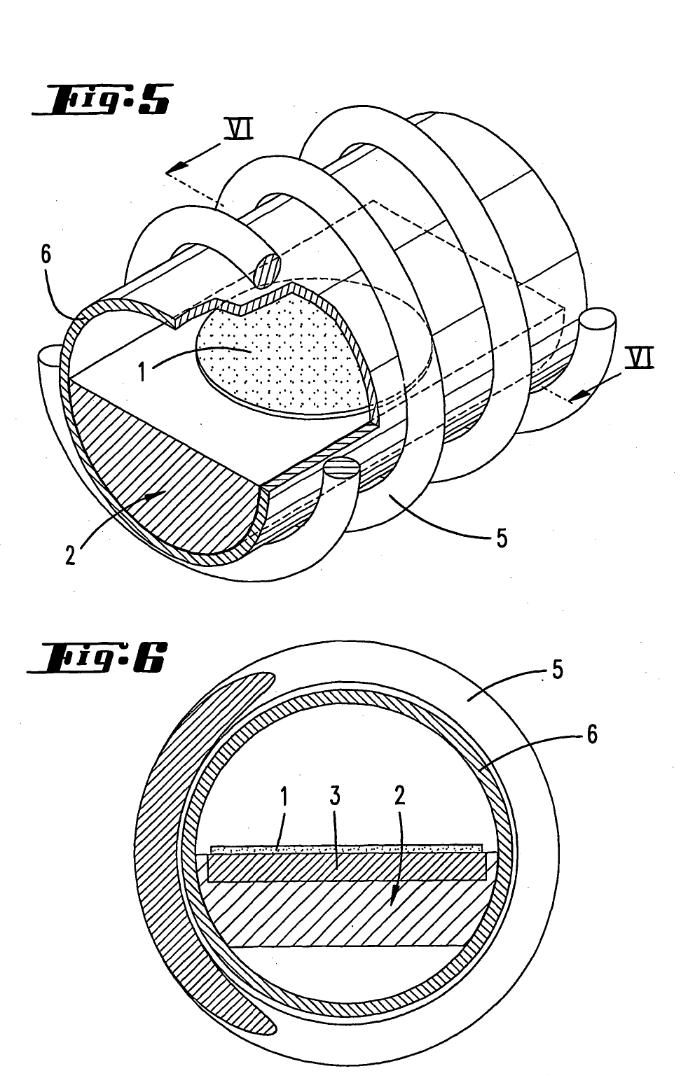

The exemplary embodiment illustrated in FIGS. 5 and 6 relates to a tunnel reactor. The latter comprises a quartz tube 6, around which an HF coil 5 is wound. A substrate holder 2 made from graphite is located inside the quartz tube 6, in the region of the HF coil 5. The substrate 1 rests on the planar surface of the substrate holder 2.

As can be seen from FIG. 6, an insert piece 3 is positioned in a positively locking manner inside a cutout in the substrate holder 2, virtually precisely beneath the substrate 1. In this exemplary embodiment, the substrate 1 rests directly on the surface of the insert piece 3. The surface of the insert piece 3, which insert piece may consist of molybdenum, may, like the surface of the substrate holder surrounding the insert piece 3, be coated in a suitable way.

With the configurations which have been described above and are illustrated in the drawings, it is possible to disproportionately increase the substrate temperature compared to the surface of the substrate holder 2 surrounding the substrate. This may even reduce parasitic growth outside the substrate surface.

All features disclosed are (inherently) pertinent to the invention. The disclosure content of the associated/appended priority documents (copy of the prior application) is hereby incorporated in its entirety in the disclosure of the application, partly with a view to incorporating features of these documents in claims of the present application.

What is claimed is:

1. Device for depositing in particular crystalline layers on an in particular crystalline substrate (1), having a high-frequency-heated substrate holder (2) made from conductive material for holding the substrate (1) with surface-to-surface contact, which substrate holder (2) has a zone (3) of higher electrical conductivity, characterized in that the zone of higher electrical conductivity is associated with the supported surface of the substrate (1).

2. Device according to claim 1 or in particular according thereto, characterized in that the zone (3) of higher electrical conductivity substantially corresponds to the area taken up by the substrate (1).

3. Device according to one or more of the preceding claims or in particular according thereto, characterized in that the zone (3) is formed by an insert piece (3) made from metal in a substrate holder (2) which consists in particular of coated graphite.

4. Device according to one or more of the preceding claims, or in particular according thereto, characterized in that the substrate holder (2) has one or more substrate-bearing disks (4), which are in particular mounted on a gas bearing and each have an associated insert piece (3).

5. Device according to one or more of the preceding claims or in particular according thereto, characterized in that the insert piece (3) is directly associated with the substrate bearing disk (4) and in particular the entire substrate bearing disk (4) consists of metal.

6. Device according to one or more of the preceding claims or in particular according thereto, characterized by a multiplicity of substrate bearing disks (4) disposed in planetary fashion on a substrate holder.

7. Device according to one or more of the preceding claims or in particular according thereto, characterized in that the substrate bearing disk (4) is located on a gas bearing in a bearing recess (9) in the substrate holder and the insert piece (3) or the more electrically conductive zone is associated with the base of the bearing recess (9).

8. Device according to one or more of the preceding claims or in particular according thereto, characterized in that the one or more insert pieces consist of molybdenum, tantalum, tungsten or the like.

9. Device according to one or more of the preceding claims or in particular according thereto, characterized in that the substrate holder (2) is surrounded by an HF coil (5).

10. Device according to one or more of the preceding claims or in particular according thereto, characterized in that the substrate holder (2) is disposed above an HF coil (5).

11. Device according to one or more of the preceding claims or in particular according thereto, characterized in that the reactor, with which the substrate holder (2) is associated, is a cold-wall reactor, the walls of which are heated only by the radiation of the heated substrate holder (2).

12. Device according to one or more of the preceding claims or in particular according thereto, characterized in that the reactor is a tunnel reactor.

13. Device according to one or more of the preceding claims or in particular according thereto, characterized in that the reactor is a planetary reactor with a central gas feed and a rotating substrate holder (2), which is support for a multiplicity of substrate bearing disks (4) arranged in planetary fashion with respect to the center of the substrate holder (2), which substrate bearing disks (4) in each case rotate on a gas bearing.
